(19) United States
(12) Patent Application Publication
(10) Pub. No.: US 2024/0132684 A1
(43) Pub. Date: Apr. 25, 2024

(54) GLASS FABRIC, PREPREG, AND PRINTED CIRCUIT BOARD

(71) Applicant: ASAHI KASEI KABUSHIKI KAISHA, Tokyo (JP)

(72) Inventors: Amane HIROSE, Tokyo (JP); Hiroyuki HONMA, Tokyo (JP)

(73) Assignee: ASAHI KASEI KABUSHIKI KAISHA, Tokyo (JP)

(21) Appl. No.: 18/277,696

(22) PCT Filed: Oct. 10, 2021
(86) PCT No.: PCT/JP2021/037621

§ 371 Date: Aug. 16, 2023

(30) Foreign Application Priority Data
Apr. 8, 2021 (JP) 2021-066637

(51) Int. Cl. C08J 5/24; C03C 3/06; C03C 13/00; D03D 1/00; D03D 15/267; D03D 15/50; D06M 13/513; H05K 1/03

(52) U.S. Cl. CPC C08J 5/248; C03C 3/06; C03C 13/00; D03D 1/0082; D03D 15/267; D03D 15/50; D06M 13/5135; H05K 1/0306; H05K 1/038; C03C 2201/02; C03C 2213/00; D06M 2101/00

(57) ABSTRACT

Provided is a glass fabric formed by weaving warp and weft glass yarns comprising a plurality of glass filaments, wherein the surface of the glass fabric is subjected to surface treatment with a surface treatment agent, and the total carbon extraction amount when the glass fabric is subjected to extraction with methanol is greater than 0 and not more than 0.25%.

### FIELD

The present invention relates to a glass fabric, a prepreg, and a printed circuit board.

### BACKGROUND

Currently, due to the high performance of information terminals such as smartphones and high-speed communication represented by 5G communication, in printed circuit boards for high-speed communication, the dielectric constant and dissipation factor of insulating materials used to reduce transmission loss have been significantly reduced.

Examples of insulating materials for printed circuit boards for high-speed communication are reported in Patent Literature 1 and 2. Specifically, a laminate in which prepregs obtained by impregnating glass fabrics with a low dielectric thermosetting resin or a thermoplastic resin such as a polyphenylene ether terminal-modified with a vinyl or methacryloxy group (hereinafter referred to generically as a “matrix resin”) and drying are laminated and cured under heat and pressure is known (Patent Literature 1 and 2). According to Patent Literature 1 and 2, a low dielectric constant and a low dissipation factor are also required for such glass fabrics.

As a method for reducing the dielectric constant and the dissipation factor of a glass fabric, Patent Literature 3 indicates a problem of hydroxyl groups on a glass surface as one of the reasons for an increase in the dissipation factor of a glass fabric, and discloses a method for reducing the amount of hydroxyl groups on the glass surface with a surface treatment agent.

### CITATION LIST

### Patent Literature

[PTL 1] WO 2019/065940
[PTL 2] WO 2019/065941
[PTL 3] Japanese Unexamined Patent Publication (Kokai) No. 2020-194888

### SUMMARY

### Technical Problem

However, in Patent Literature 3, the improvement of the dissipation factor of a silica glass fabric at 10 GHz is 1.0×10⁻³ to 1.0×10⁻⁴, and the improvement effect is considered to be small. From this, it is considered that there are factors other than the presence of hydroxyl groups on the glass surface that increase the dissipation factor of the glass fabric, and there is room for improvement. Thus, an object of the present invention is to provide a glass fabric having a dissipation factor near the bulk dissipation factor of glass, as well as a prepreg and printed circuit board using the same.

### Solution to Problem

As a result of investigation in order to achieve the object described above, the present inventors have discovered that the cause of an increase in the dissipation factor of a glass fabric is organic matter which remains physically adhering to a glass yarn surface, and have completed the present invention. Specifically, the present inventors have discovered that the cause is attributed to very small amounts of thermal oxidation degradation products of the sizing agent which could not be reduced by heat cleaning, as well as residues and modification products of surface treatment agents, such as silane coupling agents, which physically adhere to the glass surface without forming chemical bonds and which cannot be reduced (for example, removed) by washing with water, and have completed the present invention. Some of the aspects of the present invention are exemplified below.

[1]

A glass fabric comprising glass yarns composed of a plurality of glass filaments and woven as warp and weft yarns, wherein the glass fabric is surface-treated on a surface thereof with a surface treatment agent, and has a total carbon extraction amount of greater than 0 and 0.25% or less when the glass fabric is subjected to extraction with methanol.

[2]

The glass fabric according to Item 1, wherein the glass yarns contain 95 wt % to 100 wt % of silicon (Si) in terms of silicon dioxide (SiO₂).

[3]

The glass fabric according to Item 1 or 2, wherein the glass yarns contain 99.0 wt % to 100 wt % of Si in terms of SiO₂.

[4]

The glass fabric according to any one of Items 1 to 3, wherein the glass yarns contain 99.9 wt % to 100 wt % of Si in terms of SiO₂.

[5]

The glass fabric according to any one of Items 1 to 4, wherein the surface treatment agent comprises a silane coupling agent represented by the following formula (1):

X(R)₃₋ₙSiYₙ (1)
where X is an organic functional group having at least one of a radical-reactive unsaturated double bond group and an amino group; each Y is independently an alkoxy group; n is an integer of 1 to 3; and each R is independently a group selected from the group consisting of a methyl group, an ethyl group, and a phenyl group.
   [6]

The glass fabric according to Item 5, where X in formula (1) is an organic functional group that does not form a salt with an ionic compound.

[7]

The glass fabric according to Item 5 or 6, wherein X in formula (1) does not contain an amine or an ammonium cation.

[8]

The glass fabric according to any one of Item 5 to 7, wherein X in formula (1) is an organic functional group having one or more methacryloxy groups or acryloxy groups.

[9]

The glass fabric according to any one of Items 1 to 8, wherein the total carbon extraction amount is 0.20% or less.

[10]

The glass fabric according to Item 9, wherein the total carbon extraction amount is 0.10% or less.

[11]

The glass fabric according to Item 10, wherein the total carbon extraction amount is 0.08% or less.

[12]

The glass fabric according to Item 11, wherein the total carbon extraction amount is 0.05% or less.

[13]

The glass fabric according to any one of Item 1 to 12, wherein glass constituting the glass yarns has a bulk dissipation factor of greater than 0 and 2.5×10⁻³ or less at 10 GHz.

[14]

The glass fabric according to Item 13, wherein the bulk dissipation factor of the glass constituting the glass yarns is 2.0×10⁻³ or less at 10 GHz.

[15]

The glass fabric according to Item 14, wherein the bulk dissipation factor of the glass constituting the glass yarns is 1.7×10⁻³ or less at 10 GHz.

[16]

The glass fabric according to Item 15, wherein the bulk dissipation factor of the glass constituting the glass yarns is 1.5×10⁻³ or less at 10 GHz.

[17]

The glass fabric according to Item 16, wherein the bulk dissipation factor of the glass constituting the glass yarns is 1.2×10⁻³ or less at 10 GHz.

[18]

The glass fabric according to any one of Items 1 to 17, wherein the glass fabric has a dissipation factor of greater than 0 and 1.0×10⁻³ or less at 10 GHz.

[19]

The glass fabric according to any one of Items 1 to 18, wherein the glass fabric after methanol extraction has a total carbon amount of 0.010% to 0.380%.

[20]

The glass fabric according to any one of Items 1 to 19, wherein the glass fabric after methanol extraction has a total carbon amount of 0.013% to 0.250%.

[21]

The glass fabric according to any one of Items 1 to 20, wherein the glass fabric after methanol extraction has a total carbon amount of 0.015% to 0.180%.

[22]

The glass fabric according to any one of Items 1 to 21, wherein the glass fabric after methanol extraction has a total carbon amount of 0.018% to 0.150%.

[23]

The glass fabric according to any one of Items 1 to 22, wherein the glass fabric after methanol extraction has a total carbon amount of 0.020% to 0.100%.

[24]

The glass fabric according to any one of Items 1 to 23, wherein the glass fabric prior to methanol extraction has a total carbon amount of 0.020% to 0.500%.

[25]

The glass fabric according to any one of Items 1 to 24, wherein the glass fabric prior to methanol extraction has a total carbon amount of 0.022% to 0.400%.

[26]

The glass fabric according to any one of Items 1 to 25, wherein the glass fabric prior to methanol extraction has a total carbon amount of 0.023% to 0.300%.

[27]

The glass fabric according to any one of Items 1 to 26, wherein the glass fabric prior to methanol extraction has a total carbon amount of 0.024% to 0.200%.

[28]

The glass fabric according to any one of Items 1 to 27, wherein the glass fabric prior to methanol extraction has a total carbon amount of 0.025% to 0.100%.

[29]

The glass fabric according to any one of Items 1 to 28, which is for a printed circuit board substrate.

[30]

A prepreg, comprising the glass fabric according to any one of Items 1 to 29, and a thermosetting resin.

[31]

A printed circuit board, comprising the prepreg according to Item 30.

[32]

A method for producing a glass fabric, comprising:
washing, with an organic solvent, a glass fabric which has been subjected to surface treatment with a surface treatment agent represented by the following formula (1):

X(R)₃₋ₙSiYₙ (1)
where X is an organic functional group having at least one of a radical-reactive unsaturated double bond group and an amino group; each Y is independently an alkoxy group; n is an integer of 1 to 3; and each R is independently a group selected from the group consisting of a methyl group, an ethyl group, and a phenyl group.
   [33]

The method for producing a glass fabric according to Item 32, wherein X in formula (1) is an organic functional group that is not in the form a salt with an ionic compound.

[34]

The method for producing a glass fabric according to Item 32 or 33, wherein X in formula (1) does not contain an amine or an ammonium cation.

[35]

The method for producing a glass fabric according to any one of Items 32 to 34, wherein X in formula (1) is an organic functional group having one or more methacryloxy groups or acryloxy groups.

[36]

The method for producing a glass fabric according to any one of Items 32 to 35, wherein the organic solvent is methanol.

### Advantageous Effects of Invention

According to the present invention, there can be provided a glass fabric having a dissipation factor near the bulk dissipation factor of glass, as well as a prepreg and printed circuit board using this glass fabric.

### DESCRIPTION OF EMBODIMENTS

An embodiment (hereinafter referred to as “present embodiment”) of the present invention will be described in detail below, but the present invention is not limited thereto, and various changes can be made within a scope which does not deviate from the spirit thereof.

In the present embodiment, numerical ranges described using “to” include the numerical values before and after “to” within the numerical range. Further, in the present embodiment, in numerical ranges described in stages, the upper limit or lower limit described in a certain numerical range may be replaced with the upper limit or lower limit of another numerical range described in stages. Further, in the present embodiment, the upper limit value or lower limit value described in a certain numerical range can be replaced with the values shown in the Examples. In the present embodiment, the term “step” includes not only independent steps but also steps which cannot be clearly distinguished from other steps, as long as the purpose of the step is achieved.

### [Glass Fabric]

The glass fabric of the present embodiment is a glass fabric comprising glass yarns composed of a plurality of glass filaments and woven as warp and weft yarns. The glass fabric according to the present embodiment is surface treated with a surface treatment agent and has a specific value as the extraction amount at the time of methanol extraction. The surface treatment agent, as described later, is used for treating the surfaces of the glass yarns (including glass filaments).

### [Methanol Extraction Amount]

The surface-treated glass fabric according to the present embodiment has an extraction amount of 0.25% or less by methanol extraction. The configuration of the surface-treated glass fabric having a dissipation factor close to the bulk dissipation factor of glass is specified by a methanol extraction amount of 0.25% or less. The methanol extraction amount is obtained from the difference in total carbon amount (%) between a glass fabric which has not been subjected to methanol extraction and the glass fabric which has been subjected to methanol extraction, and is described in detail in the Examples. Examples of components extracted by methanol extraction include unnecessary components that adhere to the glass fabric and should be reduced (for example, components derived from the sizing agent or components derived from the silane coupling agent that are not chemically bonded to glass). Specifically, the significance of using the methanol extraction amount is that such unnecessary components can be indirectly ascertained using the total carbon amount. In the present description, the extraction amount of a glass fabric by methanol extraction may be referred to as the “total carbon extraction amount.”

In order for the surface-treated glass fabric to exhibit excellent dielectric properties, the methanol extraction amount is preferably less than 0.25%, more preferably 0.20% or less, further preferably 0.10% or less, even further preferably 0.08% or less, and particularly preferably 0.05% or less. The lower limit of the methanol extraction amount of the surface-treated glass fabric is not particularly limited, and may be, for example, 0% or greater than 0%.

Though not to be bound by theory, it is considered that the amount of methanol extracted from the surface-treated glass fabric can be adjusted within the numerical range described above by:
selecting a surface treatment agent to suppress the residual and occurrence of (i) or (ii) below; and
in the glass fabric production step, optimizing conditions in, for example, the heat de-oiling (heat de-sizing) step, residual size reduction step, fixing step, washing step, drying step, finish washing step, and finish drying step.
(i) very small amounts of thermal oxidation degradation products of a sizing agent which remain physically adhering to the glass yarn surface; and
(ii) residues or modification products of the surface treatment agent which physically adhere to the glass surface without forming chemical bonds and which cannot be reduced by washing with water.

### [Average Filament Diameter]

The average filament diameter of the glass filaments is preferably 2.5 to 9.0 μm, more preferably 2.5 to 7.5 μm, further preferably 3.5 to 7.0 μm, even further preferably 3.5 to 6.0 μm, and particularly preferably 3.5 to 5.0 μm.

### [Thread Count]

The warp and weft yarns constituting the glass fabric preferably have a thread count of 10 to 120 yarns/inch (=10 to 120 yarns/25.4 mm), more preferably 40 to 100 yarns/inch, and further preferably 40 to 100 yarns/inch.

### [Fabric Weight]

The fabric weight (basis weight) of the glass fabric is preferably 8 to 250 g/m², more preferably 8 to 100 g/m², further preferably 8 to 80 g/m², and particularly preferably 8 to 50 g/m².

### [Weave Structure]

The weave structure of the glass fabric is not particularly limited, and examples thereof include weave structures such as plain weave, Nanako weave, satin weave, and twill weave. Among these, the plain weave structure is more preferable.

### [Glass Type]

Glass fabrics used for laminates are conventionally composed of a glass called E-glass (non-alkali glass). Conversely, in the glass fabric of the present embodiment, for example, L-glass, NE-glass, D-glass, L2-glass, T-glass, silica glass, or quartz glass may be used. From the viewpoint of dielectric properties, L-glass, L2-glass, silica glass, and quartz glass are more preferably used, and among these, silica glass and quartz glass are particularly preferable.

Since the lower the bulk dissipation factor of glass is, the more remarkable the effect of the present invention is, the silicon (Si) content of the glass yarns constituting the glass fabric, in terms of silicon dioxide (SiO₂), is preferably in the range of 95 wt % to 100 wt %, more preferably in the range of 99 wt % to 100 wt %, further preferably in the range of 99.5 wt % to 100 wt %, and particularly preferably in the range of 99.9 wt % to 100 wt %.

### [Bulk Dissipation Factor of Glass]

The present inventors have discovered that for glass species in which an increase in the dissipation factor is remarkably observed due to the presence of thermal oxidation degradation products of the sizing agent or residues and modification products of surface treatment agent, the lower the dissipation factor, the more easily the dissipation factor increases. Thus, the range of the bulk dissipation factor of glass, in which the effect of the present invention is likely to be exhibited, is, at 10 GHz, preferably 2.5×10⁻³ or less, more preferably 2.0×10⁻³ or less, further preferably 1.7×10⁻³ or less, even further preferably 1.5×10⁻³ or less, and particularly preferably 1.2×10⁻³ or less. Note that the lower limit of the bulk dissipation factor of glass constituting the glass yarns of the present embodiment may be, for example, “greater than 0” at 10 GHz.

Furthermore, the composition of each glass and the bulk dissipation factor exhibit the following relationships:
glass of 99 wt % or more in terms of SiO₂: bulk dissipation factor≤1.2×10⁻³.
glass of 50% or more in terms of SiO₂, 20% or more in terms of boron dioxide (B₂O₃), and 3% or more in terms of diphosphorus pentoxide (P₂O₅): bulk dissipation factor≤1.7×10⁻³.
glass of 50% or more in terms of SiO₂, 20% or more in terms of B₂O₃, 0.4% or more in terms of strontium oxide (SrO): bulk dissipation factor≤1.7×10⁻³

### [Glass Yarns and Silane Coupling Agent]

The glass yarns (including glass filaments) constituting the glass fabric are preferably surface-treated with a silane coupling agent. It is preferable that a silane coupling agent represented by the following formula (1):

X(R)₃₋ₙSiYₙ (1)
where X is an organic functional group having at least one of a radical-reactive unsaturated double bond group and an amino group; each Y is independently an alkoxy group; n is an integer of 1 to 3; and R is a group selected from the group consisting of a methyl group, an ethyl group, and a phenyl group, be used as the silane coupling agent.

From the viewpoint of reduced inhibition of reactivity with the resin, the silane coupling agent is preferably nonionic. Among nonionic silane coupling agents, silane coupling agents having at least one group selected from the group consisting of vinyl groups, methacryloxy groups, and acryloxy groups are preferable, and among these, silane coupling agents having at least one methacryloxy group or acryloxy group are particularly preferable. The heat resistance or reliability of the printed circuit board can be enhanced by not inhibiting the reactivity with the resin.

In formula (1), X is an organic functional group having at least one of an unsaturated double bond group and an amino group. Thus, in addition to an aspect in which X has both an unsaturated double bond group and an amino group, an aspect in which X has an unsaturated double bond group but does not have an amino group and an aspect in which X does not have an unsaturated double bond group but has an amino group are included in the scope of formula (1).

The present embodiment focuses on the fact that:
(i) very small amounts of thermal oxidation degradation products of the sizing agent which remain physically adhering to the glass yarn surface; and
(ii) residues or modification products of the surface treatment agent which physically adhere to the glass surface without forming chemical bonds and which cannot be reduced by washing with water are the reasons for the increase in the dissipation factor of conventional glass fabrics. From the viewpoint of suppressing the generation of the (i) thermal oxidation degradation products or (ii) modification products described above, X in formula (1) is preferably an organic functional group which does not form a salt with an ionic compound. From the viewpoint of reactivity with the matrix resin, X in formula (1) is more preferably an organic functional group having one or more methacryloxy groups or acryloxy groups. From the viewpoint of facilitating expression of the effect of the present invention, X in formula (1) preferably does not contain an amine such as a primary amine, secondary amine, or tertiary amine, or an ammonium cation such as a quaternary ammonium cation.

Regarding Y in formula (1) above, as the alkoxy group, any form can be used, and an alkoxy group having 1 to 5 carbon atoms (1, 2, 3, 4 or 5 carbon atoms) is preferably for stabilizing the glass fabric.

As the surface treatment agent, the silane coupling agent represented by formula (1) may be used alone, or two or more silane coupling agents with different Xs in formula (1) may be used in combination. As the silane coupling agent represented by formula (1), for example, known simple substances such as vinyltrimethoxysilane, 3-methacryloxypropyltrimethoxysilane, acryloxypropyltrimethoxysilane, 3-acryloxypropyltrimethoxysilane, 5-hexenyltrimethoxysilane, or mixtures thereof can be used.

The molecular weight of the silane coupling agent is preferably 100 to 600, more preferably 150 to 500, and further preferably 200 to 450. Among these, it is particularly preferable to use two or more silane coupling agents having different molecular weights. By treating the glass yarn surface with two or more types of silane coupling agent having different molecular weights, the density of the treatment agent on the glass surface tends to increase, further improving the reactivity with the matrix resin.

### [Glass Fabric Production Method]

The method for the production of a glass fabric of the present embodiment is not particularly limited, and may comprise, for example, the following steps:
a heat de-sizing step in which the glass fabric is de-sized by heating at an arbitrary temperature of 300° C. to 1000° C.;
a coating step in which a silane coupling agent is caused to adhere to the surface of the glass filaments using a treatment solution having a concentration of 0.1 to 3.0 wt %;
a fixing step in which the silane coupling agent is fixed to the surface of the glass filaments by heat drying;
a washing step in which silane coupling agent which did not form chemical bonds with the surface of the glass filament is washed away with water;
a drying step (heat drying step) in which the glass fabric is heat-dried after washing; and
a finishing washing step in which residues and modification products of the silane coupling agent which did not form chemical bonds with the surface of the glass filament and which could not be reduced with water, are reduced. The coating step, the fixing step, the washing step, and the finishing washing step may be performed on the glass yarns before the weaving step in which the glass yarns are woven to obtain the glass fabric, or may be performed on the glass fabric after the weaving step. The method for producing the glass fabric may further include, if necessary, a residual size reduction step to reduce the denatured sizing agent remaining in the heat de-sizing step, and an opening filament step to open the glass yarns of the glass fabric after the weaving step. When the washing step is performed after the weaving step, the washing step may be performed using a high-pressure water spray to serve as the opening filament step. The composition of the glass fabric conventionally does not change before and after opening.

It is believed that as a result of the above production method, the adhering organic matter which increases dissipation factor can be removed, whereby a silane coupling agent layer can be formed on the surface of each individual glass filament constituting a glass yarn.

Examples of the residual size reduction step include dry cleaning such as plasma irradiation and UV ozone; wet cleaning such as high-pressure water washing, organic solvent washing, nanobubble water washing, and ultrasonic water washing; and heat cleaning at a temperature higher than the heat de-sizing step, and a plurality of these may be combined. However, as the residual size reduction step, short-time heat cleaning in which the glass fabric is passed through a heating furnace at 800° C. or higher from roller to roller is preferable.

As the method for applying the treatment solution to the glass fabric in the coating step, (a) a method of accumulating the treatment solution in a bath and immersing and passing the glass fabric therethrough (hereinafter referred to as “immersion method”) or (b) a method of applying the treatment solution directly to the glass fabric with a roll coater, die coater, gravure coater, etc., may be adopted. In the case of coating by the immersion method of (a) above, it is preferable to select the immersion time of the glass fabric in the treatment solution so as to be 0.5 seconds or more and 1 minute or less.

As the method of heat drying the solvent after applying the treatment solution to the glass fabric, known methods such as hot air and electromagnetic waves may be adopted.

The heat drying temperature is preferably 80° C. or higher, and more preferably 90° C. or higher, so that the reaction between the silane coupling agent and the glass is sufficiently carried out. The heat drying temperature is preferably 300° C. or lower, and more preferably 180° C. or lower, in order to prevent deterioration of the organic functional groups of the silane coupling agent.

The finishing washing step is not particularly limited as long as it is a method which can reduce residues and modification products of the silane coupling agent that have not formed chemical bonds with the surface of the glass filament, and which cannot be reduced with water, and examples thereof include washing with an organic solvent. In another aspect of the present embodiment, there is provided a glass fabric production method including a step of washing the glass fabric which has been surface-treated with the surface treatment agent represented by the above general formula (1) with an organic solvent. According to this production method, even if a raw material such as quartz glass is used, the dissipation factor of the resulting glass fabric can be maintained near the bulk dissipation factor.

In order to reduce the residues and modification products of the silane coupling agent which cannot be reduced with water, as the finishing washing step, washing with a highly hydrophobic organic solvent or an organic solvent having a high affinity for the residues and modification products of the silane coupling agent having a hydroxyl group is preferable. As the washing method, a known method such as an immersion method or shower spraying can be used, and heating and cooling may be performed as necessary. In order to prevent matter dissolved from matter adhering to the glass fabric from readhering, it is preferable to reduce excess solvent with a squeezing roller after washing and before final drying of the glass fabric. The organic solvent to be used is not particularly limited, and examples of highly hydrophobic organic solvents include:
saturated chain aliphatic hydrocarbons such as n-pentane, i-pentane, n-hexane, i-hexane, n-heptane, i-heptane, n-octane, i-octane, 2,2,4-trimethylpentane (isooctane), n-nonane, i-nonane, n-decane, i-decane, and 2,2,4,6,6-pentamethylheptane (isododecane);
saturated cycloaliphatic hydrocarbons such as cyclopentane, cyclohexane, methylcyclohexane, dimethylcyclohexane, ethylcyclohexane;
aromatic hydrocarbons such as benzene, toluene, xylene, ethylbenzene, diethylbenzene, trimethylbenzene, triethylbenzene;
halogen-containing solvents such as chloroform, dichloromethane, dichloroethane. Examples of organic solvents having a high affinity for modification products of silane coupling agents include alcohols such as methanol, ethanol and butanol, ketones such as acetone and methyl ethyl ketone, ethers such as methyl ethyl ether and diethyl ether;
amides such as N,N-dimethylformamide and N,N-dimethylacetamide; and
dimethyl sulfoxide. Among these, aromatic hydrocarbons, alcohols, and ketones are preferable, and from the viewpoint of bringing the dissipation factor of the obtained glass fabric near the bulk dissipation factor, methanol is more preferable.

The method for the production of a glass fabric preferably comprises a drying step in order to reduce the amount of organic solvent after washing, and the organic solvent used for washing preferably has a boiling point of 120° C. or lower, because the amount of the organic solvent can be easily reduced by drying. For drying the organic solvent, a known method such as heat drying or air drying can be used.

When heat drying is performed to reduce the organic solvent, a known method can be used, but from the viewpoint of safety, hot air drying using low-pressure steam or heat medium oil as a heat source is preferable. The drying temperature is preferably equal to or higher than the boiling point of the washing solvent, and is preferably 180° C. or lower from the viewpoint of suppressing deterioration of the silane coupling agent.

The opening filament method of the opening filament step is not particularly limited, and examples thereof include a method of opening the glass fabric with sprayed water (high-pressure water opening), a vibro-washer, ultrasonic water, or mangle. By reducing the tension applied to the glass fabric during this fiber opening process, there is a tendency that the air permeability can be reduced. In order to suppress a reduction in the tensile strength of the glass fabric due to the opening processing, it is preferable to take measures such as reducing the friction of the contact member when weaving the glass yarns, optimizing the sizing agent, and increasing the adhesion amount.

The method for the production of the glass fabric may comprise optional steps after the opening filament step. The optional steps are not particularly limited, and includes, for example, a slitting step.

### [Prepreg]

The prepreg of the present embodiment comprises at least the glass fabric and a matrix resin with which the glass fabric is impregnated. As a result, prepregs having few voids can be provided.

Either of a thermosetting resin or a thermoplastic resin can be used as the matrix resin.

The thermosetting resin is not particularly limited, and examples thereof include:
a) an epoxy resin obtained by adding a compound having an epoxy group and a compound having at least one of an epoxy group-reactive amino group, phenol group, acid anhydride group, hydrazide group, isocyanate group, cyanate group, or hydroxyl group without a catalyst, or with the addition of a catalyst having a reaction catalytic ability such as an imidazole compound, a tertiary amine compound, a urea compound, or a phosphorus compound, and thereafter reacting and curing;
b) a radically polymerizable curable resin obtained by curing a compound having at least one of an allyl group, a methacrylic group, and an acrylic group using a thermal decomposition catalyst or a photodecomposition catalyst as a reaction initiator;
c) a maleimide triazine resin obtained by reacting and curing a compound having a cyanate group and a compound having a maleimide group;
d) a thermosetting polyimide resin obtained by reacting and curing a maleimide compound and an amine compound; and
e) a benzoxazine resin obtained by cross-linking and curing a compound having a benzoxazine ring by heat polymerization.

The thermoplastic resin is not particularly limited, and examples thereof include polyphenylene ether, modified polyphenylene ether, polyphenylene sulfide, polysulfone, polyethersulfone, polyarylate, aromatic polyamide, polyetheretherketone, thermoplastic polyimide, insoluble polyimide, poly amideimide, and fluorine resin.

Furthermore, in the present embodiment, a thermosetting resin and a thermoplastic resin may be used together. The prepreg may optionally comprise an inorganic filler. An inorganic filler is preferably used in combination with a thermosetting resin. The inorganic filler may be, for example, aluminum hydroxide, zirconium oxide, calcium carbonate, alumina, mica, aluminum carbonate, magnesium silicate, aluminum silicate, silica, talc, short glass fibers, aluminum borate, or silicon carbide.

### [Printed Circuit Board]

The printed circuit board of the present embodiment comprises the prepreg described above. As a result, a printed circuit board having excellent insulation reliability can be provided.

[Method for Measuring Dissipation Factor of Glass fabric]

The dielectric property evaluation method of present embodiment includes a step of measuring the dielectric properties of a fabric using the resonance method. The measurement method in the measurement step described above is not limited to a specific method as long as it is a measurement method using the resonance method. According to this measuring method, measurement can be performed more simply and accurately as compared to a conventional measurement method in which a substrate as a measurement sample is produced and the dielectric properties are evaluated. The reason why the dielectric properties of a fabric can be easily and accurately measured by using the resonance method is that, though not to be bound by theory, the resonance method is suitable for evaluating low-loss materials in the high-frequency range. In addition to the resonance method, the lumped parameter method and the reflection transmission method are known as dielectric property evaluation methods. In the lumped parameter method, it is necessary to form a capacitor by interposing the measurement sample between two electrodes, and as a result, there is a problem in that the operation is very complicated. Furthermore, the reflection transmission method has a problem in that it is difficult to evaluate the dissipation factor of a sample with high accuracy when evaluating a low-loss material because of the strong influence of port-matching characteristics. For the above reasons, the resonance method is preferable as a method for evaluating the dielectric properties of the fabric.

In this measurement step, preferred measurement instruments using the resonance method include split cylinder resonators, open resonators, and NRD guide excitation dielectric resonators. However, if the principles of the resonance method are used, the dielectric properties of the fabric may be evaluated using equipment other than the measuring equipment described above.

In order to measure the dielectric properties of the fabric used for printed circuit boards for high-speed communication, regarding the measurable range of the measuring instrument, for the dielectric constant (Dk) and the dissipation factor (Df), Dk=1.1 Fm⁻¹ to 50 Fm⁻¹ and Df=1.0×10⁻⁶ to 1.0×10⁻¹ are preferable, Dk=1.5 Fm⁻¹ to 10 Fm⁻¹ and Df=1.0×10⁻⁵ to 5.0×10⁻¹ are more preferable, and Dk=2.0 Fm⁻¹ to 5 Fm⁻¹ and Df=5.0×10⁻⁵ to 1.0×10⁻² are further preferable.

It is preferable that the measurable frequency of the measuring equipment be 10 GHz or higher. When the frequency is 10 GHz or more, the characteristics can be evaluated in what is assumed to be the frequency band region when the glass fabric is actually used for printed circuit board substrates for high-speed communication.

In order to measure the dielectric properties of the fabric in a larger area to determine whether the measurement results are within the preset reference value range, the area measured by the measuring method is preferably 10 mm² or more. The area measured by the measuring method is more preferably 15 mm² or more, and further preferably 20 mm² or more.

The measurable thickness of the sample is not particularly limited, and is preferably 3 μm to 300 μm, more preferably 5 μm to 200 μm, and further preferably 7 μm to 150 μm.

### [Measurement of Bulk Dissipation Factor]

The bulk dissipation factor of glass constituting the glass fabric can be measured, for a glass plate with a thickness of 300 μm or less, using the same method as the measurement of the dissipation factor of the glass fabric. The glass fabric according to the present embodiment is preferably for a printed circuit board substrate. Furthermore, the bulk dissipation factor of glass constituting the glass yarns, at 10 GHz, is preferably 2.5×10⁻³ or less, more preferably 2.0×10⁻³ or less, further preferably 1.7×10⁻³ or less, even further preferably 1.5×10⁻³ or less, and particularly preferably 1.2×10⁻³ or less or 1.0×10⁻³ or less. According to this, it becomes easy to bring the dissipation factor of the glass fabric near the bulk dissipation factor of the glass in the production of the printed circuit board base material.

### [Total Carbon Amount of Glass Fabric Before Methanol Extraction]

The total carbon amount of the glass fabric before methanol extraction is preferably 0.020% to 0.500%, more preferably 0.022% to 0.400%, further preferably 0.023 to 0.300%, even further preferably 0.024% to 0.200%, and particularly preferably 0.025% to 0.100%. According to this, it becomes easy to obtain an aspect in which the amount of the physically adhering silane coupling agent, which should originally be reduced, is reduced while maintaining suitable insulation reliability.

### [Total Carbon Amount of Glass Fabric After Methanol Extraction]

The total carbon amount of the glass fabric after methanol extraction is preferably 0.010% to 0.380%, more preferably 0.013% to 0.250%, further preferably 0.015% to 0.180%, even further preferably 0.018% to 0.150%, and particularly preferably 0.020% to 0.100%. According to this, it becomes easy to obtain an aspect in which the amount of the physically adhering silane coupling agent, which should originally be reduced, is reduced while maintaining suitable insulation reliability.

### [Relationship Between Methanol Extraction and Glass Fabric of Present Embodiment]

As described above, one of the requirements of the glass fabric of the present embodiment is that the total carbon extraction amount by methanol extraction is greater than 0 and 0.25% or less.

The present embodiment includes glass fabrics having a total carbon amount within the above range before methanol extraction, and also includes glass fabrics having a total carbon amount within the above range after methanol extraction.

### EXAMPLES

Next, the present invention will be described in further detail by means of Examples and Comparative Examples. The present invention is not limited by the following examples. Various evaluation methods will also be described below.

### [Method for Measuring Thickness of Glass Fabric]

In accordance with 7.10 of JIS R 3420, using a micrometer, a spindle is gently rotated and brought into light parallel contact with the measurement surface, and the scale is read after the ratchet sounded three times. JIS R 3420 defines general test methods for glass long fibers and products such as glass fabrics using glass long fibers.

### [Method for Measuring Basis Weight (Fabric Weight)]

The basis weight of the fabric is obtained by cutting the fabric to a predetermined size and dividing the weight by the sample area. In these Examples and Comparative Examples, the basis weight of each glass fabric was determined by cutting the glass fabric to a size of 10 cm² and measuring the weight.

### [Converted Thickness]

Since the glass fabric is a discontinuous planar body composed of air and glass, the converted thickness required for measurement by the resonance method is calculated by dividing the basis weight of each glass fabric by the density.

Converted thickness (μm)=basis weight (g/m²)÷density (g/cm³)

### [Dissipation Factor Measurement Method]

The dissipation factor of each glass fabric is measured in accordance with IEC 62562. Specifically, a glass fabric sample having a size required for measurement with each resonator is stored in a constant temperature and humidity oven at 23° C. and 50% RH for 8 hours or more to adjust the humidity. Thereafter, the dielectric properties are measured using a split cylinder resonator (manufactured by EM Lab) and an impedance analyzer (manufactured by Agilent Technologies). Measurement is performed five times for each sample, and the average value is obtained. The thickness of each sample is measured using the converted thickness described above. IEC 62562 defines methods for measuring dielectric properties in the microwave band of fine ceramic materials for dielectric substrates used mainly in microwave circuits.

### [Total Carbon Amount of Glass Fabric]

The surface-treated glass fabric is heated at 800° C. for 1 minute, and the amount of carbon dioxide in the generated gas is measured by gas chromatography to obtain the amount of carbon dioxide in the generated gas. The total carbon amount of the surface-treated glass fabric is determined by comparing the amount of carbon dioxide generated when a predetermined amount of acetanilide (C₈H₉NO) was similarly heated at 800° C. for 1 minute in advance. A Sumigraph NC-90A (manufactured by Sumika Chemical Analysis Service) is used for measurement.
Molecular weight of acetanilide=135.17
Carbon ratio of acetanilide=71.09%

Specifically, the total carbon amount of the glass fabric is calculated based on the following formula.

Total carbon amount of glass fabric=[{weight of acetanilide×(carbon ratio of acetanilide/100)}/peak area derived from carbon dioxide generated from acetanilide]×{(peak area of carbon dioxide generated from glass fabric/weight of glass fabric)×100}

Note that when determining the total carbon amount of the glass fabric before methanol extraction, the glass fabric before methanol extraction should be the measurement target, and when determining the total carbon amount of the glass fabric after methanol extraction, the glass fabric after methanol extraction should be the measurement target.

### [Method for Measuring Methanol Extraction Amount]

The amount of methanol extracted from the glass fabric is determined from the difference in total carbon amount (%) between the glass fabric which has not been subjected to methanol extraction and the glass fabric which has been subjected to methanol extraction. Methanol extraction is performed by immersing 5 mg of the glass fabric in 100 ml of methanol at room temperature for 1 minute. This reduces the surface treatment agent physically adhering to the glass fabric. The total carbon amount of the glass fabric is measured using a Sumigraph NC-90A (manufactured by Sumika Chemical Analysis Service).

### Example 1

As the warp yarns were used silica glass yarns having an average filament diameter of 5.0 μm, 100 filaments, and a twist number of 1.0 Z, while as the weft yarns were used silica glass yarns having an average filament diameter of 5.0 μm, 100 filaments, and a twist number of 1.0 Z. Using an air jet loom, a glass fabric was woven at a thread count of 66 warp yarns/25 mm and 68 weft yarns/25 mm. The resulting green fabric was heat-treated at 600° C. for 2 hours for de-sizing. The glass fabric was immersed in a treatment solution containing 0.9% of 3-methacryloxypropyltrimethoxysilane; Z6030 (manufactured by Dow Toray Industries, Inc.) as a silane coupling agent dispersed in pure water adjusted to pH=3 with acetic acid. After squeezing out the solution, the fabric was dried by heating at 110° C. for 1 minute to fix the silane coupling agent. After washing the dried glass fabric with water followed by heat drying at 110° C. for 1 minute, the glass fabric was immersed in methanol for finish washing, thereby reducing the denatured products of the silane coupling agent which did not form chemical bonds with the surface of the glass filaments. By drying at 110° C. for 1 minute after finishing washing, a glass fabric A in which the physically adhering modification products of the silane coupling agent were reduced was obtained.

### Example 2

A glass fabric B in which the physically adhering modification products of the silane coupling agent were reduced was obtained in the same manner as in Example 1, except that the heat drying time in the fixing step was set to 5 minutes.

### Example 3

A glass fabric C in which the physically adhering modification products of the silane coupling agent were reduced was obtained in the same manner as in Example 1, except that the heat drying time in the fixing step was set to 10 minutes.

### Example 4

A glass fabric D in which the physically adhering modification products of the silane coupling agent were reduced was obtained in the same manner as in Example 2, except that in the finishing washing step, toluene was used as the organic solvent.

### Example 5

A glass fabric E in which the physically adhering modification products of the silane coupling agent were reduced was obtained in the same manner as in Example 2, except that in the finishing washing step, acetone was used as the organic solvent.

### Example 6

A glass fabric F in which the physically adhering modification products of the silane coupling agent and a very small amount of thermal oxidation degradation products of the sizing agent were reduced was obtained in the same manner as in Example 1, except that after the de-sizing step, additional heating was performed at 800° C. for 15 seconds for residual size reduction, and the drying temperature in the drying step was set to 130° C.

### Example 7

A glass fabric G in which the physically adhering modification products of the silane coupling agent and a very small amount of thermal oxidation degradation products of the sizing agent were reduced was obtained in the same manner as in Example 6 except that the heat de-oiling step was performed at 800° C. for 30 seconds and residual size reduction was not performed.

### Example 8

A glass fabric H in which the physically adhering modification products of the silane coupling agent and a very small amount of thermal oxidation degradation products of the sizing agent were reduced was obtained in the same manner as in Example 3 except that after the de-sizing step of heating at 360° C. for 48 hours, additional heating was performed at 800° C. for 15 seconds for residual size reduction.

### Example 9

A glass fabric I in which the physically adhering modification products of the silane coupling agent were reduced was obtained in the same manner as in Example 7 except that a treatment solution in which 0.9% of 5-hexenyltrimethoxysilane; Z6161 (manufactured by Dow Toray Industries, Inc.) as the silane coupling agent was dispersed was used.

### Example 10

A glass fabric J in which the physically adhering modification products of the silane coupling agent were reduced was obtained in the same manner as in Example 7 except that a treatment solution in which 0.9% of 3-acryloxypropyltrimethoxysilane; KBM-5103 (manufactured by Shin-Etsu Silicone Co., Ltd.) as the silane coupling agent was dispersed was used.

### Example 11

A glass fabric K in which the physically adhering modification products of the silane coupling agent were reduced was obtained in the same manner as in Example 7 except that a treatment solution in which 0.45% of 5-hexenyltrimethoxysilane; Z6161 (manufactured by Dow Toray) and 0.45% of 3-methacryloxypropyltrimethoxysilane; Z6030 (manufactured by Dow Toray) as silane coupling agents were dispersed was used.

### Example 12

A glass fabric L in which the physically adhering modification products of the silane coupling agent were reduced was obtained in the same manner as in Example 7 except that a treatment solution in which 0.45% of 3-acryloxypropyltrimethoxysilane; KBM-5103 (manufactured by Shin-Etsu Silicone Co., Ltd.) and 0.45% of 3-methacryloxypropyltrimethoxysilane; Z6030 (manufactured by Dow Toray) as silane coupling agents were dispersed was used.

### Comparative Example 1

The green fabric obtained in Example 1 was heat-treated at 360° C. for 48 hours for de-sizing. The glass fabric was then immersed in a treatment solution in which as 0.9% of 3-methacryloxypropyltrimethoxysilane; Z6030 (manufactured by Dow Toray Industries, Inc.) as the silane coupling agent was dispersed in pure water adjusted to pH=3 with acetic acid. After squeezing out the solution, the fabric was heat-dried at 110° C. for 1 minute to fix the silane coupling agent. By washing the dried glass fabric with water and drying at 110° C. for 1 minute, a glass fabric I was obtained without performing the finishing washing step and the final drying step.

### Comparative Example 2

A glass fabric J was obtained in the same manner as in Comparative Example 1, except that the heat drying time in the fixing step was set to 5 minutes.

### Comparative Example 3

A glass fabric K was obtained in the same manner as in Comparative Example 1, except that the heat drying time in the fixing step was set to 10 minutes.

### Comparative Example 4

A glass fabric L was obtained in the same manner as in Comparative Example 1, except that the heat de-oiling step was performed at 800° C. for 15 seconds.

The production conditions and evaluation results of the Examples and Comparative Examples are shown in Table 1.

TABLE 1

| | Ex 1 | Ex 2 | Ex 3 | Ex 4 | Ex 5 | Ex 6 |
|---|---|---|---|---|---|---|
| Glass fabric No. | A | B | C | D | E | F |
| Heat de-oiling step | 600° C./2 hr | 600° C./2 hr | 600° C./2 hr | 600° C./2 hr | 600° C./2 hr | 600°° C./2 hr |
| Residual size reduction | — | — | — | — | — | 800° C./15 sec |
| step | | | | | | |
| Fixing step | 110° C./1 min | 110° C./5 min | 110° C./10 min | 110° C./5 min | 110° C./5 min | 110° C./1 min |
| Washing step | with water | with water | with water | with water | with water | with water |
| Drying step | 110° C./1 min | 110° C./1 min | 110° C./1 min | 110° C./1 min | 110° C./1 min | 130° C./1 min |
| Finish washing step | Methanol | Methanol | Methanol | Toluene | Acetone | Methanol |
| | immersion | immersion | immersion | immersion | immersion | immersion |
| Finish drying step | 110° C./1 min | 110° C./1 min | 110° C./1 min | 110° C./1 min | 110° C./1 min | 110° C./1 min |
| Dissipation factor of glass | 0.00042 | 0.00040 | 0.00077 | 0.00050 | 0.00050 | 0.00023 |
| fabric @ 10 GHz | | | | | | |
| Total carbon content | 0.116% | 0.177% | 0.410% | 0.234% | 0.195% | 0.037% |
| before methanol extraction | | | | | | |
| Total carbon content after | 0.046% | 0.094% | 0.323% | 0.086% | 0.094% | 0.036% |
| methanol extraction | | | | | | |
| Extraction amount by | 0.071% | 0.083% | 0.087% | 0.148% | 0.101% | 0.001% |
| methanol extraction | | | | | | |
| (Total carbon extraction | | | | | | |
| amount) | | | | | | |

TABLE 2

| | Ex 7 | Ex 8 | Ex 9 | Ex 10 | Ex 11 | Ex 12 |
|---|---|---|---|---|---|---|
| Glass fabric No. | G | H | I | J | K | L |
| Heat de-oiling step | 800° C./30 sec | 360° C./48 hr | 800° C./30 sec | 800° C./30 sec | 800° C./30 sec | 800° C./30 sec |
| Residual size reduction | — | 800° C./15 sec | — | — | — | — |
| step | | | | | | |
| Fixing step | 110° C./1 min | 110° C./10 min | 110° C./1 min | 110° C./1 min | 110° C./1 min | 110° C./1 min |
| Washing step | with water | with water | with water | with water | with water | with water |
| Drying step | 130° C./1 min | 110° C./1 min | 130° C./1 min | 130° C./1 min | 130° C./1 min | 130° C./1 min |
| Finish washing step | Methanol | Methanol | Methanol | Methanol | Methanol | Methanol |
| | immersion | immersion | immersion | immersion | immersion | immersion |
| Finish drying step | 110° C./1 min | 110° C./1 min | 110° C./1 min | 110° C./1 min | 110° C./1 min | 110° C./1 min |
| Dissipation factor of glass | 0.00025 | 0.00060 | 0.00028 | 0.00024 | 0.00027 | 0.00030 |
| fabric @ 10 GHz | | | | | | |
| Total carbon content | 0.039% | 0.370% | 0.060% | 0.055% | 0.070% | 0.064% |
| before methanol extraction | | | | | | |
| Total carbon content after | 0.038% | 0.357% | 0.049% | 0.038% | 0.053% | 0.053% |
| methanol extraction | | | | | | |
| Extraction amount by | 0.001% | 0.013% | 0.011% | 0.017% | 0.017% | 0.011% |
| methanol extraction | | | | | | |
| (Total carbon extraction | | | | | | |
| amount) | | | | | | |

TABLE 3

| | Comp Ex 1 | Comp Ex 2 | Comp Ex 3 | Comp Ex 4 | Comp Ex 5 |
|---|---|---|---|---|---|
| Glass fabric No. | I | J | K | L | M |
| Heat de-oiling step | 360° C./48 hr | 360° C./48 hr | 360° C./48 hr | 800° C./15 sec | 360° C./48 hr |
| Residual size reduction step | — | — | — | — | — |
| Fixing step | 110° C./1 min | 110° C./5 min | 110° C./10 min | 110° C./1 min | 110° C./1 min |
| Washing step | with water | with water | with water | with water | Methanol |
| | | | | | immersion |
| Drying step | 110° C./1 min | 110° C./1 min | 110° C./1 min | 110° C./1 min | 110° C./1 min |
| Finish washing step | — | — | — | — | — |
| Finish drying step | — | — | — | — | — |
| Dissipation factor of glass fabric @ 10 GHz | 0.00159 | 0.00111 | 0.00189 | 0.00109 | 0.00128 |
| Total carbon content before methanol | 0.665% | 0.542% | 1.053% | 0.615% | 0.105% |
| extraction | | | | | |
| Total carbon content after methanol | 0.068% | 0.177% | 0.495% | 0.060% | 0.060% |
| extraction | | | | | |
| Extraction amount by methanol extraction | 0.598% | 0.365% | 0.557% | 0.556% | 0.046% |
| (Total carbon extraction amount) | | | | | |

### INDUSTRIAL APPLICABILITY

The glass fabric of the present invention has industrial applicability as a base material for printed circuit boards used in the electronic and electrical fields.

1. A glass fabric comprising glass yarns composed of a plurality of glass filaments and woven as warp and weft yarns, wherein the glass fabric is surface-treated on a surface thereof with a surface treatment agent, and has a total carbon extraction amount of greater than 0 and 0.25% or less when the glass fabric is subjected to extraction with methanol.

2. The glass fabric according to claim 1, wherein the glass yarns contain 95 wt % to 100 wt %, 99.0 wt % to 100 wt %, or 99.9 wt % to 100 wt % of silicon (Si) in terms of silicon dioxide (SiO₂).

3. (canceled)

4. (canceled)

5. The glass fabric according to claim 1, wherein the surface treatment agent comprises a silane coupling agent represented by the following formula (1):
X(R)₃₋ₙSiYₙ (1)
where X is an organic functional group having at least one of a radical-reactive unsaturated double bond group and an amino group; each Y is independently an alkoxy group; n is an integer of 1 to 3; and each R is independently a group selected from the group consisting of a methyl group, an ethyl group, and a phenyl group.

6. The glass fabric according to claim 5, where X in formula (1) is an organic functional group that does not form a salt with an ionic compound.

7. The glass fabric according to claim 5, wherein X in formula (1) does not contain an amine or an ammonium cation.

8. The glass fabric according to claim 5, wherein X in formula (1) is an organic functional group having one or more methacryloxy groups or acryloxy groups.

9. The glass fabric according to claim 1, wherein the total carbon extraction amount is 0.20% or less, 0.10% or less, 0.08% or less, or 0.05% or less.

10-12. (canceled)

13. The glass fabric according to claim 1, wherein glass constituting the glass yarns has a bulk dissipation factor of greater than 0 and 2.5×10⁻³ or less, 2.0×10⁻³ or less, 1.7×10⁻³ or less, 1.5×10⁻³ or less, or 1.2×10⁻³ or less at 10 GHz.

14-17. (canceled)

18. The glass fabric according to claim 1, wherein the glass fabric has a dissipation factor of greater than 0 and 1.0×10⁻³ or less at 10 GHz.

19. The glass fabric according to claim 1, wherein the glass fabric after methanol extraction has a total carbon amount of 0.010% to 0.380%, 0.013% to 0.250%, 0.015% to 0.180%, 0.018% to 0.150%, or 0.020% to 0.100%.

20.-23. (canceled)

24. The glass fabric according to claim 1, wherein the glass fabric prior to methanol extraction has a total carbon amount of 0.020% to 0.500%, 0.022% to 0.400%, 0.023% to 0.300%, 0.024% to 0.200%, or 0.025% to 0.100%.

25.-28. (canceled)

29. The glass fabric according to claim 1, which is for a printed circuit board substrate.

30. A prepreg, comprising the glass fabric according to claim 1, and a thermosetting resin.

31. A printed circuit board, comprising the prepreg according to claim 30.

32. A method for producing a glass fabric, comprising:
washing, with an organic solvent, a glass fabric which has been subjected to surface treatment with a surface treatment agent represented by the following formula (1):
X(R)₃₋ₙSiYₙ (1)
where X is an organic functional group having at least one of a radical-reactive unsaturated double bond group and an amino group; each Y is independently an alkoxy group; n is an integer of 1 to 3; and each R is independently a group selected from the group consisting of a methyl group, an ethyl group, and a phenyl group.

33. The method for producing a glass fabric according to claim 32, wherein X in formula (1) is an organic functional group that is not in the form a salt with an ionic compound.

34. The method for producing a glass fabric according to claim 32, wherein X in formula (1) does not contain an amine or an ammonium cation.

35. The method for producing a glass fabric according to claim 32, wherein X in formula (1) is an organic functional group having one or more methacryloxy groups or acryloxy groups.

36. The method for producing a glass fabric according to claim 32, wherein the organic solvent is methanol.
